(19) United States
(12) Patent Application Publication
(10) Pub. No.: US 2012/0069684 A1
(43) Pub. Date: Mar. 22, 2012

(54) SEMICONDUCTOR INTEGRATED CIRCUIT

(75) Inventors: Toshiaki Douzaka, Yokohama-shi (JP); Toshiyuki Kouchi, Kawasaki-shi (JP); Atsushi Nakayama, Yokohama-shi (JP)

(73) Assignee: KABUSHIKI KAISHA TOSHIBA, Minato-ku (JP)

(21) Appl. No.: 13/053,443

(22) Filed: Mar. 22, 2011

(30) Foreign Application Priority Data
Sep. 17, 2010 (JP) 2010-210136

(51) Int. Cl. G11C 7/10; G11C 7/12; G11C 7/00

(52) U.S. Cl. 365/189.05; 365/189.011; 365/203

(57) ABSTRACT

According to one embodiment, a semiconductor integrated circuit includes a memory cell array includes data storage units which are arranged at intersections of word lines and bit lines and hold data, a reversing circuit which logically reverses held data stored in the data storage units, and a flag bit column which stores, for each row, a flag for identifying presence/absence of logic reversal of data stored in the data storage units.

### CROSS-REFERENCE TO RELATED APPLICATIONS

This application is based upon and claims the benefit of priority from Japanese Patent Application No. 2010-210136, filed Sep. 17, 2010; the entire contents of which are incorporated herein by reference.

### FIELD

Embodiments described herein relate generally to a semiconductor integrated circuit.

### BACKGROUND

The performance of a MOS transistor of, e.g., an SRAM macro manufactured by a manufacturing process using advanced micropatterning often degrades due to NBTI deterioration and PBTI deterioration. PBTI deterioration occurs when a negative bias is continuously applied to the gate of a PMOS transistor. NBTI deterioration occurs when a positive bias is continuously applied to the gate of an NMOS transistor.

When a positive or negative bias is continuously applied as described above, the absolute value of the threshold voltage of a transistor increases, and the propagation delay time of a circuit increases with time. These deteriorations are promoted as the temperature rises. Accordingly, the internal temperature of a recent micropatterned semiconductor chip is expected to rise to about a few ten degrees Celsius to a few hundred degrees Celsius. This tendency presumably becomes conspicuous.

### BRIEF DESCRIPTION OF THE DRAWINGS

FIG. 1 is a block diagram showing an example of the overall configuration of a semiconductor integrated circuit according to the first embodiment;

FIG. 2 is an equivalent circuit diagram showing a memory cell unit of the semiconductor integrated circuit according to the first embodiment;

FIG. 3 is a timing chart showing a held data reversing operation of the semiconductor integrated circuit according to the first embodiment;

FIG. 4 is a view showing average cycle counts required to change a held data reverse mode to a normal mode;

FIG. 5 is an equivalent circuit diagram showing a memory cell unit of a semiconductor integrated circuit according to the second embodiment;

FIG. 6 is a timing chart showing a held data reversing operation of the semiconductor integrated circuit according to the second embodiment;

FIG. 7 is an equivalent circuit diagram showing a memory cell unit of a semiconductor integrated circuit according to the third embodiment;

FIG. 8 is a timing chart showing a held data reversing operation of the semiconductor integrated circuit according to the third embodiment;

FIG. 9 is an equivalent circuit diagram showing a memory cell unit of a semiconductor integrated circuit according to Modification 1;

FIG. 10 is an equivalent circuit diagram showing a memory cell unit of a semiconductor integrated circuit according to Modification 2;

FIG. 11 is an equivalent circuit diagram showing a memory cell unit of a semiconductor integrated circuit according to Modification 3;

FIG. 12 is an equivalent circuit diagrams showing reversing circuit examples of the semiconductor integrated circuit according to Modification 3;

FIG. 13 is a timing chart showing a held data reversing operation of the semiconductor integrated circuit according to Modification 3;

FIG. 14 is an equivalent circuit diagram showing a memory cell unit of a semiconductor integrated circuit according to Modification 4;

FIG. 15 is an equivalent circuit diagram showing a reversing circuit example of the semiconductor integrated circuit according to Modification 4;

FIG. 16 is an equivalent circuit diagram showing a memory cell unit of a semiconductor integrated circuit according to Modification 5;

FIG. 17 is an equivalent circuit diagrams showing reversing circuit examples of the semiconductor integrated circuit according to Modification 5;

FIG. 18 is a timing chart showing a held data reversing operation of the semiconductor integrated circuit according to Modification 5;

FIG. 19 is an equivalent circuit diagram showing a memory cell unit of a semiconductor integrated circuit according to Modification 6;

FIG. 20 is an equivalent circuit diagram showing a reversing circuit example of the semiconductor integrated circuit according to Modification 6; and

FIG. 21 is a timing chart showing a held data reversing operation of the semiconductor integrated circuit according to Modification 6.

### DETAILED DESCRIPTION

In general, according to one embodiment, a semiconductor integrated circuit includes a memory cell array including data storage units which are arranged at intersections of word lines and bit lines and hold data, a reversing circuit which logically reverses held data stored in the data storage units, and a flag bit column which stores, for each row, a flag for identifying the presence/absence of logic reversal of data stored in the data storage units.

Embodiments will be explained below with reference to the accompanying drawing. Note that in this explanation, the same reference numerals denote the same parts throughout the drawing.

### First Embodiment

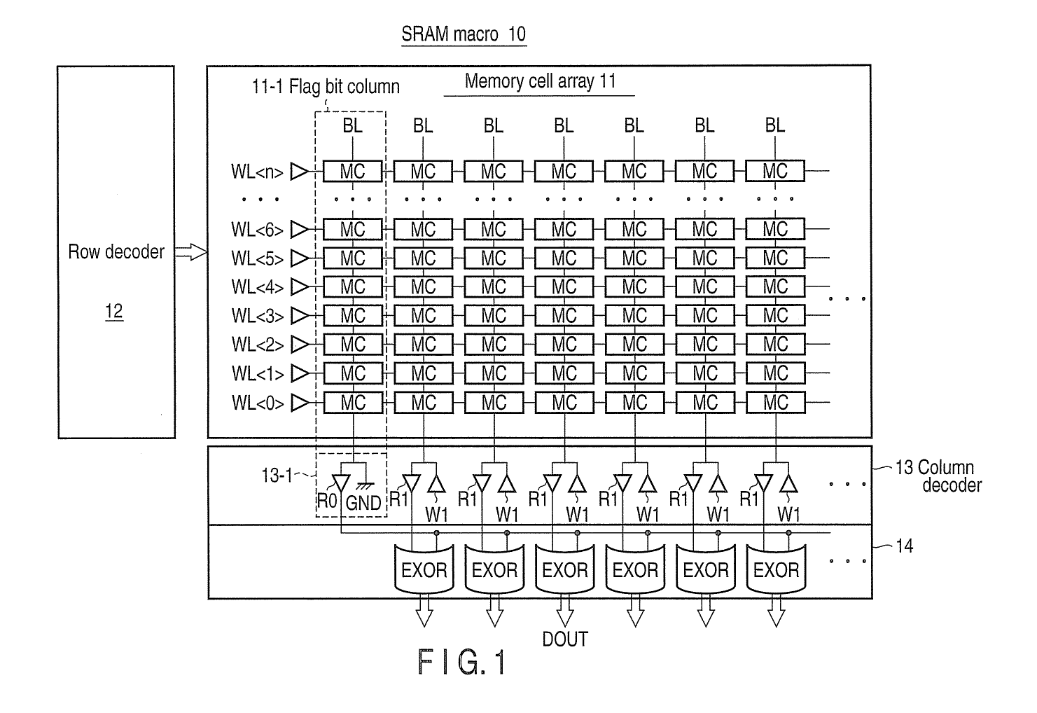

A semiconductor integrated circuit according to the first embodiment will be explained below with reference to FIGS. 1, 2, 3, and 4.

In the following explanation, an SRAM (Static Random Access Memory) macro will be taken as an example of the semiconductor integrated circuit.

### 1. Configuration Example

### 1-1. Overall Configuration Example

First, an example of the overall configuration of the semiconductor integrated circuit according to the first embodiment will be explained below with reference to FIG. 1.

As shown in FIG. 1, an SRAM macro 10 according to the first embodiment includes a memory cell array 11, row decoder 12, column decoder 13, and output circuit 14.

The memory cell array 11 includes memory cell units MC arranged in a matrix at the intersections of bit lines BL and word lines WL. In this embodiment, the memory cell unit MC includes an SRAM cell for holding data as a memory cell, and a reversing circuit. Details will be described later. In addition, the memory cell array 11 according to this embodiment includes a flag bit column 11-1. The flag bit column 11-1 is one column for storing, for each row, a flag for identifying the presence/absence of logic reversal of held data in the memory cell unit MC, and has the same arrangement as that of the memory cell unit MC. The flag bit column 11-1 and a flat bit write/read circuit 13-1 (to be described later) form a flag circuit.

The row decoder 12 performs control in the row direction of the memory cell array 11 under the control of a controller (not shown). For example, the row decoder 12 applies voltages necessary for data write and read to the word lines (WL<0> to WL<n>).

The column decoder 13 performs control in the column direction of the memory cell array 11 under the control of the controller (not shown). For example, the column decoder 13 applies voltages necessary for data write and read to the bit lines BL.

In addition, the column decoder 13 according to this embodiment includes write circuits W1, read circuits R1, and the flag bit write/read circuit 13-1 forming the flag circuit. The write circuit W1 writes data in the memory cell unit MC. The read circuit R1 reads out data from the memory cell unit MC to the output circuit 14.

The flag bit write/read circuit 13-1 forming the flag circuit writes “L”-level data by applying a ground power supply voltage GND as a write voltage to the flag bit column 11-1, and reads out data from the flag bit column 11-1 to the output circuit 14 by a read circuit R0. Thus, the flag bit write/read circuit 13-1 performs flag bit write/read for each row, and makes it possible to switch a data reverse mode (to be described later) to a normal mode by software.

The output circuit 14 includes a plurality of switching circuits EXOR. The switching circuit EXOR receives data read out from the memory cell unit MC by the read circuit R1, and outputs readout data from the memory cell unit MC in accordance with data of the flag bit column 11-1 read out by the read circuit R0 forming the flag circuit.

More specifically, when data is written in the memory cell unit MC in the normal mode, the write circuit 13-1 (GND) writes data “L” in the flag bit column 11-1.

Furthermore, when held data in the memory cell unit MC is reversed in the held data reverse mode (to be described later), held data in the flag bit column 11-1 is also similarly reversed (to data “H”).

Accordingly, when data is read out from the memory cell unit MC in the normal mode, the output circuit 14 outputs the readout data after reversing it or without reversing it in accordance with the data level of the flag bit column 11-1.

As described above, this embodiment includes the flag circuit (11-1 and 13-1) for identifying the presence/absence of logic reversal of held data in the memory cell unit MC. Therefore, when reversing the logic of held data in the memory cell unit MC for each row as in this embodiment, a data direction recognition flag bit need only be one bit.

In the arrangement according to this embodiment as described above, held data in the memory cell units MC can be switched by software for each row (on the row basis). When switching the data reverse mode (to be described later) to the normal mode, therefore, data reversal need not be performed on all bits. This is advantageous for a high-speed operation because the time for switching to the normal mode can be shortened.

Note that write data to the flag column 11-1 is “L”-level data in this embodiment, but the present embodiment is similarly applicable even when this write data is “H”-level data. Note also that the present embodiment is not limited to this arrangement, and, if a plurality of bit lines are connected, flag bits equal in number to the connected bits may be formed.

### 1-2. Configuration Example of Memory Cell Unit

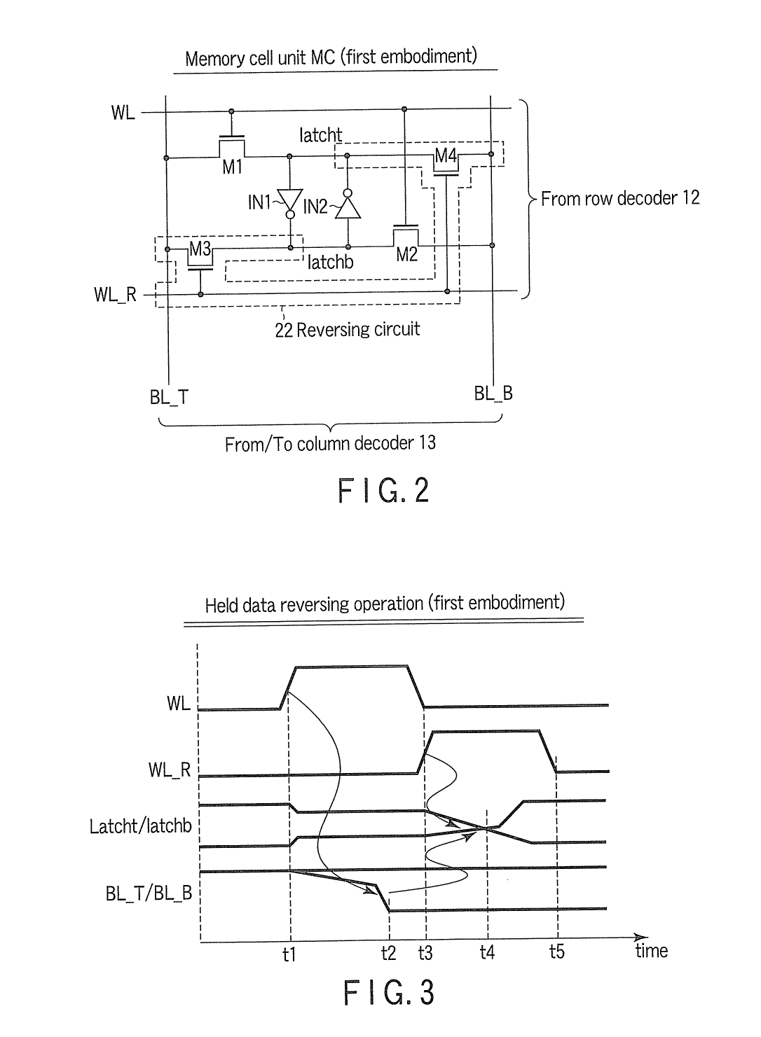

A configuration example of the memory cell unit will be explained below with reference to FIG. 2.

As shown in FIG. 2, the memory cell unit MC according to this embodiment includes an SRAM cell as a memory cell, and a reversing circuit 22.

The SRAM cell is a data storage unit which is placed at the intersections of a pair of word lines WL and WL_R and a pair of bit lines BL_B and BL_T, and latches data. The SRAM cell includes n-type transistors M1 and M2, and inverters IN1 and IN2 as latch circuits. The current path of the transistor M1 has one end connected to the bit line BL_T and the other end connected to a latch node latcht, and the gate of the transistor M1 is connected to the word line WL. The current path of the transistor M2 has one end connected to the bit line BL_B and the other end connected to a latch node latchb, and the gate of the transistor M2 is connected to the word line WL. The inverter IN1 has an input connected to the output of the inverter IN2, and an output connected to the input of the inverter IN2.

As will be described later, the reversing circuit 22 reverses held data stored in the SRAM cell. In this embodiment, the reversing circuit 22 includes n-type transistors M3 and M4. The current path of the transistor M3 has one end connected to the bit line BL_T and the other end connected to the latch node latchb, and the gate of the transistor M3 is connected to the word line WL_R. The current path of the transistor M4 has one end connected to the bit line BL_B and the other end connected to the latch node latcht, and the gate of the transistor M3 is connected to the word line WL_R. In other words, the transistors M3 and M4 are transfer gates to be used in the reverse mode in which held data in the SRAM cell is logically reversed.

Note that the two transistors M3 and M4 are applied as the data reversing circuit 22 in this embodiment, but this embodiment is not limited to this. For example, it is also possible to apply one of the transistors M3 and M4, and obtain the same effect.

### 2. Held Data Reversing Operation

A held data reversing operation of the semiconductor integrated circuit according to the first embodiment will be explained below with reference to FIG. 3. The held data reversing operation is performed in order to prevent deteriorations (NBTI deterioration and PBTI deterioration) of the performance of a MOS transistor caused by a voltage applied to the gate.

FIG. 3 is a timing chart for explaining a data reversing operation in the reverse mode in which held data stored in the SRAM cell is logically reversed. The row decoder 12 controls the following operation.

As shown in FIG. 3, at time t1 in the reverse mode, the word line WL opens to “H” level, and held data in the SRAM cell drops the potential of the bit line BL_B.

Subsequently, at time t2, the potential of the bit line BL_B sufficiently drops.

At time t3, the word line WL closes to “L” level, the word line WL_R opens to “H” level, and the potentials of the latch nodes latcht and latchb start reversing due to the potential of the bit line BL_B.

At time t4, the potentials of the latch nodes latcht and latchb become almost equal.

At time t5, the potentials of the latch nodes latcht and latchb sufficiently reverse, and the word line WL_R closes to “L” level, thereby terminating the held data reversing operation.

In the held data reversing operation according to this embodiment as described above, held data in the SRAM cells can logically be reversed for each row. This is advantageous for a high-speed operation because the time required for the reversal is short.

Also, when writing reverse data, the current consumption increases because bit lines must be precharged before write. In this embodiment, however, held data can be reversed by using the bit line potential changed during read. This makes it possible to reduce an electric current to be consumed during the reversal. Note that it is also possible to further shorten the time required to logically reverse held data, by the addition of a circuit for amplifying the differential potential between bit lines.

### 3. Effects

As described above, the semiconductor integrated circuit and its operation according to the first embodiment achieve at least effects (1) and (2) described below.

(1) Deterioration of the performance of a transistor can be prevented.

The semiconductor device according to this embodiment includes the flag circuit (11-1 and 13-1) for identifying the presence/absence of logic reversal of held data in the memory cell unit MC, and the reversing circuit 22 for logically reversing held data in a memory cell.

Accordingly, as shown in, e.g., FIG. 3, it is possible to logically reverse held data in the SRAM cells for each row by performing the held data reversing operation.

This is advantageous in that it is possible to prevent deterioration of the performance of MOS transistors (e.g., the transistors forming the inverters IN1 and IN2) caused by NBTI deterioration and PBTI deterioration.

In addition, the above-mentioned transistor deteriorations are more conspicuous in transistors micropatterned at high temperatures. This embodiment can prevent these deteriorations, and hence has merits for high-temperature processing and micropatterning.

(2) The embodiment is advantageous for a high-speed operation because the data reversing time can be shortened.

In the arrangement according to this embodiment, bit lines need not be precharged before writing reverse data, and held data can simultaneously be reversed for each row. Therefore, the time required for reversal is short, and this is advantageous for a high-speed operation.

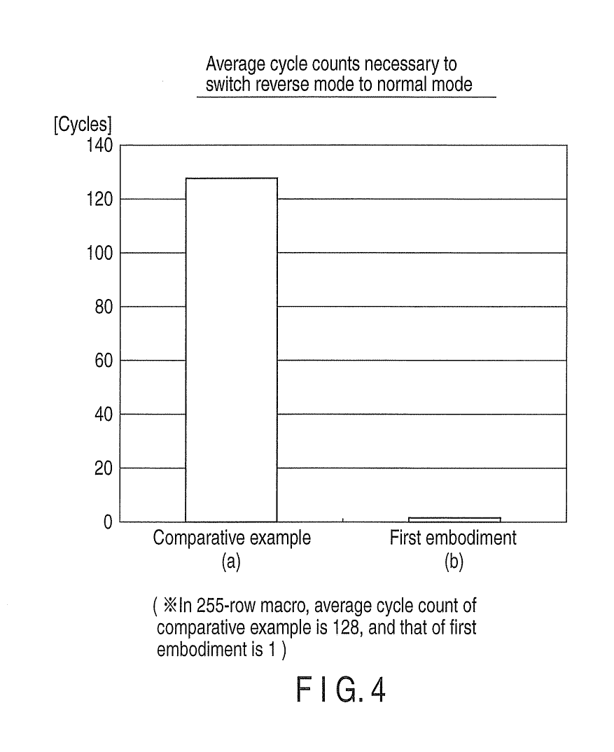

For example, FIG. 4 shows average cycle counts required to switch the held data reverse mode to the normal mode. (a) indicates the average cycle count of a comparative example, and (b) indicates that of the first embodiment. These average cycle counts are obtained for a 256-row macro. The comparative example indicated by (a) is an example of an arrangement in which bit lines are precharged before writing reverse data.

The comparative example of (a) requires 128 cycles. In the first embodiment of (b), however, data can be reversed in only one cycle because simultaneous reversal can be performed for each row. In other words, the reverse mode can be switched to the normal mode in one cycle. This embodiment can thus shorten the time of switching from the reverse mode. Consequently, this embodiment is capable of shortening the data reversing time, and obviously advantageous for a high-speed operation.

### Second Embodiment

### Another Example of Reversing Circuit

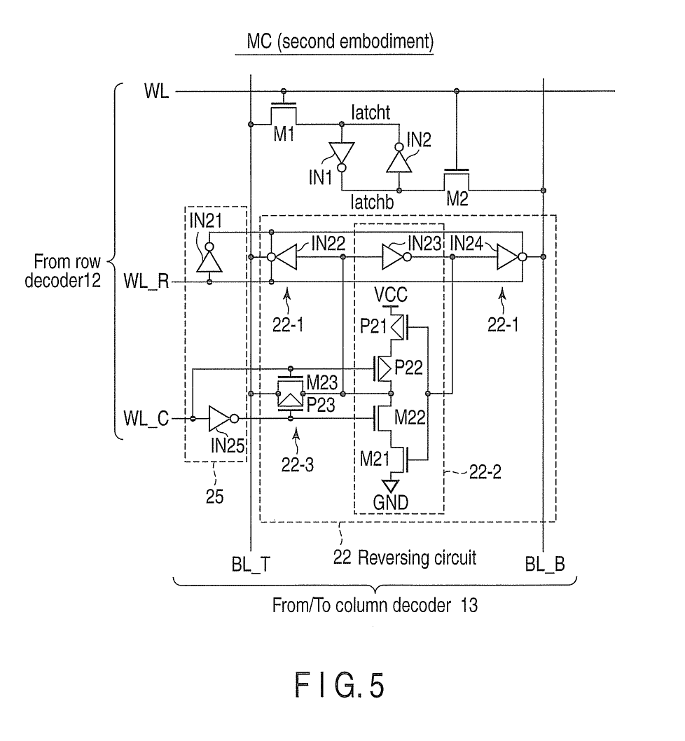

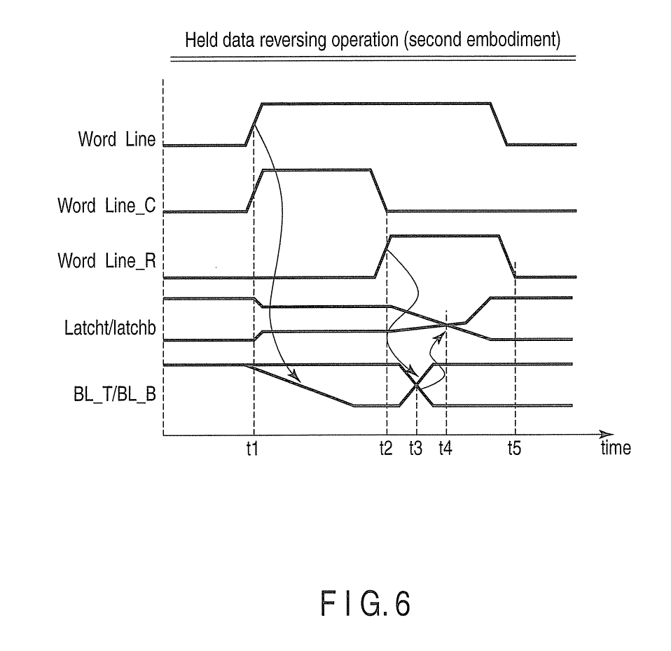

A semiconductor integrated circuit according to the second embodiment will be explained below with reference to FIGS. 5 and 6. This embodiment is directed to another example of the reversing circuit. In this explanation, a repetitive explanation of the above-mentioned first embodiment will be omitted.

### Configuration Example

### Configuration Example of Memory Cell Unit

First, a configuration example of a memory cell unit will be explained below with reference to FIG. 5.

As shown in FIG. 5, the second embodiment differs from the first embodiment in that a reversing circuit 22 includes a reverse data write circuit 22-1, data latch circuit 22-2, and data latch input circuit 22-3, and further includes a control signal circuit 25.

The reverse data write circuit 22-1 includes inverters IN22 and IN24. The inverter IN22 has an input connected to the current paths of transistors P22 and M22, and an output connected to a bit line BL_T. The inverter IN24 has an input connected to the output of an inverter IN23, and an output connected to a bit line BL_B.

The data latch circuit 22-2 includes the inverter IN23, a transistor P21, the transistor P22, the transistor M22, and a transistor M21. The inverter IN23 has an input connected to the output of the inverter IN22, and an output connected to the input of the inverter IN24. The current paths of the transistors P21, P22, M22, and M21 are sequentially connected in series between an internal power supply voltage VCC and ground power supply voltage GND. The gates of the transistors P21 and M21 are connected to the input of the inverter IN24.

The data latch input circuit 22-3 includes transistors P23 and M23. The current paths of the transistors P23 and M23 are connected to each other. The gate of the transistor P23 is connected to the output of an inverter IN25 and the gate of the transistor M22. The gate of the transistor M23 is connected to the input of the inverter IN25 and the gate of the transistor P22.

The control signal circuit 25 includes an inverter IN21 and the inverter IN25. The inverter IN21 has an input connected to a word line WL_R, and an output connected to the control terminals of the inverters IN22 and IN24. The inverter IN25 has an input connected to a word line WL_C, and an output connected to the gate of the transistor M22. The control signal circuit 25 supplies a control signal to the reversing circuit 22.

The reversing circuit 22 is formed for each bit line pair. However, the inverters IN21 and IN25 forming the control signal circuit 25 need not be formed for each reversing circuit (each bit line pair). For example, the inverters IN21 and IN25 need only be formed for each cell array block.

### <Held Data Reversing Operation>

A held data reversing operation of the semiconductor integrated circuit according to the second embodiment will be explained below with reference to FIG. 6.

As shown in FIG. 6, this embodiment differs from the first embodiment in that when the word line WL_C changes to “L” level while a word line WL is at “H” level at time t2, the word line WL_R changes to “H” level, and the potentials of latch nodes latcht and latchb start reversing.

Subsequently, at time t3, the potentials of the bit lines BL_T and BL_B become almost equal.

At time t4, the potentials of the latch nodes latcht and latchb become almost equal.

At time t5, the potentials of the latch nodes latcht and latchb sufficiently reverse, and the word line WL_R closes to “L” level, thereby terminating the held data reversing operation according to this embodiment.

### <Effects>

As described above, the semiconductor integrated circuit according to the second embodiment achieves at least the same effects as above-mentioned effects (1) and (2).

In addition, this embodiment is applicable as needed.

### Third Embodiment

### Example in which Reversal Controller Controls Reversing Circuit

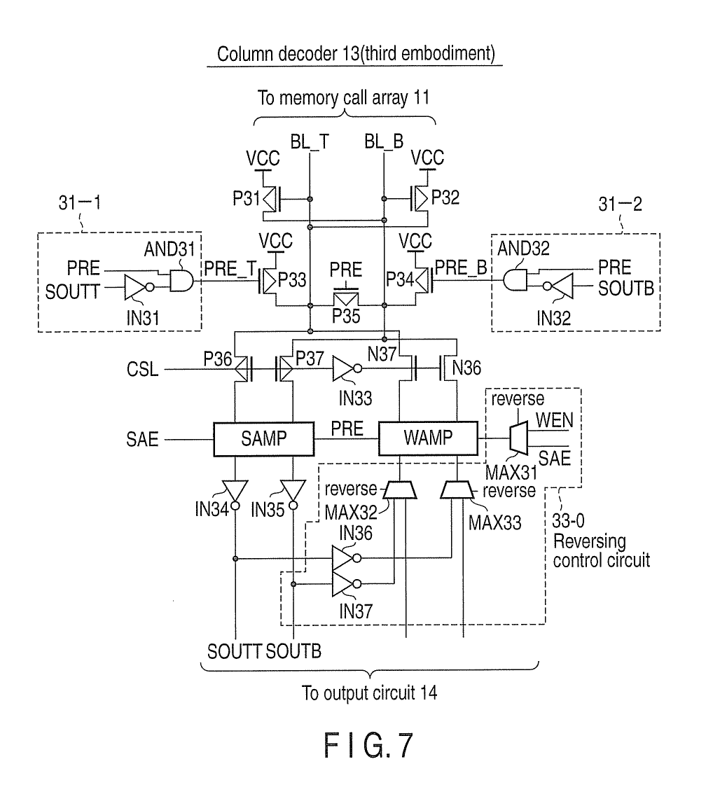

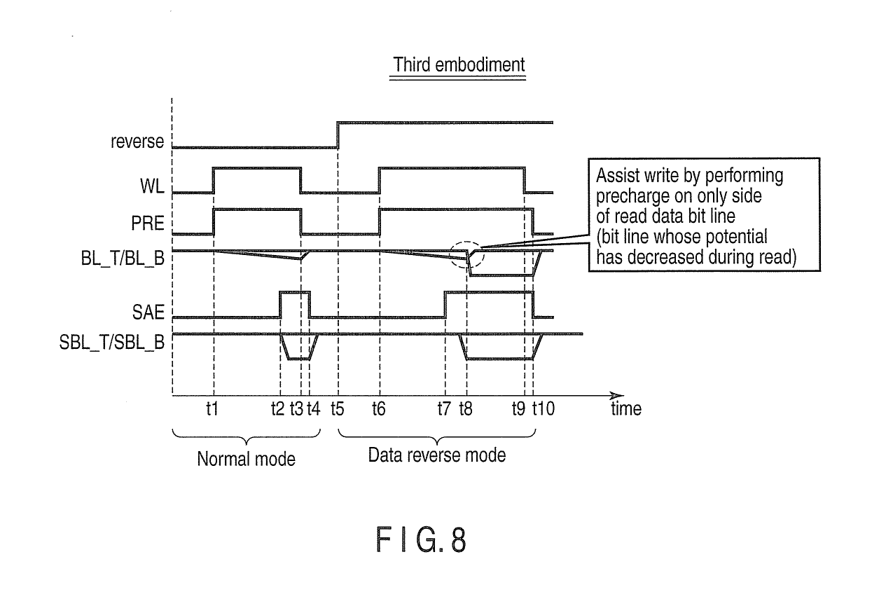

A semiconductor integrated circuit according to the third embodiment will be explained below with reference to FIGS. 7 and 8. This embodiment is directed to an example in which a reversal control circuit 33-0 installed in a column decoder controls a reversing circuit. In this explanation, a repetitive explanation of the above-mentioned first embodiment will be omitted.

### Configuration Example

### Configuration Example of Column Decoder

First, a configuration example of a column decoder 13 will be explained below with reference to FIG. 7.

As shown in FIG. 7, the column decoder 13 according to this embodiment includes precharge signal generators 31-1 and 31-2, the reversal control circuit 33-0, transistors P31 to P37, N36, and N37, inverters IN33 to IN37, a write circuit WAMP, and a read circuit SAMP.

The precharge signal generator 31-1 includes an inverter IN31 for receiving a signal SOUTT, and an AND circuit AND31 for receiving an output from the inverter IN31 and a signal PRE, and outputting a precharge signal PRE_T. The precharge signal generator 31-2 includes an inverter IN32 for receiving a signal SOUTB, and an AND circuit AND32 for receiving an output from the inverter IN32 and the signal PRE, and outputting a precharge signal PRE_B.

The reversal control circuit 33-0 includes the inverters IN36 and IN37 and multiplexers MAX31, MAX32, and MAX33, and performs control so as to reverse data by using the write circuit WAMP. The signal SOUTT is input to the input terminal of the inverter IN36. The signal SOUTB is input to the input terminal of the inverter IN37. The multiplexer MAX31 switches input signals WEN and SAE by a reverse signal reverse, and outputs the signal to the write circuit WAMP. The multiplexer MAX32 switches an output from the inverter IN37 and an input signal from an output circuit 14 by the reverse signal reverse, and outputs the signal to the write circuit WAMP. The multiplexer MAX33 switches an output from the inverter IN36 and an input signal from an input circuit (not shown) by the reverse signal reverse, and outputs the signal to the write circuit WAMP.

### <Held Data Reversing Operation>

Next, a held data reversing operation of the semiconductor integrated circuit according to the third embodiment will be explained below with reference to FIG. 8.

### Normal Mode Data Write

As shown in FIG. 8, at time t1, a word line WL and the precharge signal PRE change to “H” level while the reverse signal reverse is at “L” level.

Subsequently, at time t2, the signal SAE changes to “H” level while the reverse signal reverse is at “L” level. Consequently, data write to an SRAM cell is started, and the potential of one of bit lines BL_T and BL_B drops.

At time t3, the word line WL and precharge signal PRE change to “L” level while the reverse signal reverse is at “L” level.

At time t4, the signal SAE changes to “L” level while the reverse signal reverse is at “L” level. As a consequence, the voltage level of one of signal lines SBL_T and SBL_B rises, thereby terminating the data read operation in the normal mode.

### Data Reverse Mode

Subsequently, at time t5, the reverse signal reverse changes to “H” level, thereby starting the data reversing operation.

At time t6, the word line WL and precharge signal PRE change to “H” level while the reverse signal reverse is at “H” level. Consequently, data read from the SRAM cell is started, and the data is read out to the bit lines BL_T and BL_B.

At time t7, the signal SAE changes to “H” level while the reverse signal reverse is at “H” level.

At time t8, the voltage level of one of the signal lines SBL_T and SBL_B sufficiently decreases while the reverse signal reverse is at “H” level. As a result, the write circuit WAMP operates to start writing reverse data. The precharge signal generator 31-1 or 31-2 generates the control signal PRE_T or PRE_B for a selected bit line (a read data bit line: the bit line BL_T or BL_B whose voltage has decreased during read), thereby assisting this reverse data write.

At time t9, the word line WL changes to “L” level while the reverse signal reverse is at “H” level.

At time t10, the signals SAE and PRE change to “L” level while the reverse signal reverse is at “H” level, thereby terminating this data reverse mode.

### <Effects>

As described above, the semiconductor integrated circuit according to the third embodiment achieves at least the same effects as above-mentioned effects (1) and (2).

In addition, in this embodiment, the column decoder 13 includes the precharge signal generators 31-1 and 31-2 and reversing circuit 33.

In the data reverse mode, therefore, it is possible to generate the control signal PRE_T or PRE_B by the precharge signal generator 31-1 or 31-2, and apply the precharge voltage to the selected bit line BL_T or BL_B, thereby assisting reverse data write.

For example, when the voltage level of one of the signal lines SBL_T and SBL_B sufficiently decreases while the reverse signal reverse is at “H” level at time t8 shown in FIG. 8, the precharge signal generator 31-1 or 31-2 generates the control signal PRE_T or PRE_B for a selected bit line (a read data bit line: the bit lines BL_T or BL_B whose voltage has decreased during read), thereby assisting reverse data write.

This is advantageous in that the data reversing time can further be shortened.

### Modification 1

### Another Example in which Reversing Circuit is Installed in Column Decoder

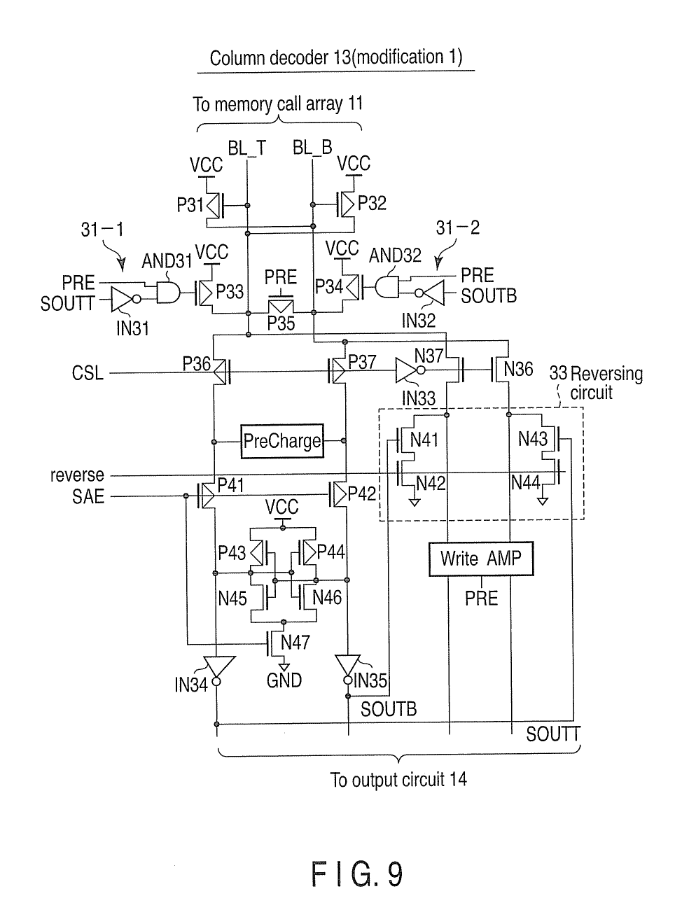

A semiconductor integrated circuit according to Modification 1 will be explained below with reference to FIG. 9. This modification is directed to another example in which a reversing circuit is installed in a column decoder 13. In this explanation, a repetitive explanation of the above-mentioned third embodiment will be omitted.

### Configuration Example

### Configuration Example of Column Decoder

A configuration example of the column decoder 13 will be explained below with reference to FIG. 9.

As shown in FIG. 9, this modification differs from the third embodiment in that the column decoder 13 includes precharge signal generators 31-1 and 31-2, a reversing circuit 33, transistors P31 to P44 and N36 to N47, inverters IN31 to IN35, a precharge circuit (PreCharge), and a write circuit Write AMP.

The reversing circuit 33 according to this modification includes the n-type transistors N41 to N44. The transistors N41 and N42 are connected in series between the source of the transistor N37 and a ground power supply voltage GND. The gate of the transistor N41 is connected to the output of the inverter IN35. A reverse signal reverse is input to the gate of the transistor N42. The transistors N43 and N44 are connected in series between the source of the transistor N36 and the ground power supply voltage GND. The gate of the transistor N43 is connected to the output of the inverter IN34. The reverse signal reverse is input to the gate of the transistor N44.

The rest of the arrangement, a normal mode, and a data reverse mode are practically the same as those described above, so a repetitive explanation will be omitted.

### <Effects>

As described above, the semiconductor integrated circuit according to Modification 1 achieves at least the same effects as above-mentioned effects (1) and (2). In addition, the arrangement of this modification is applicable as needed.

### Modification 2

### Example Further Including Precharge Circuit

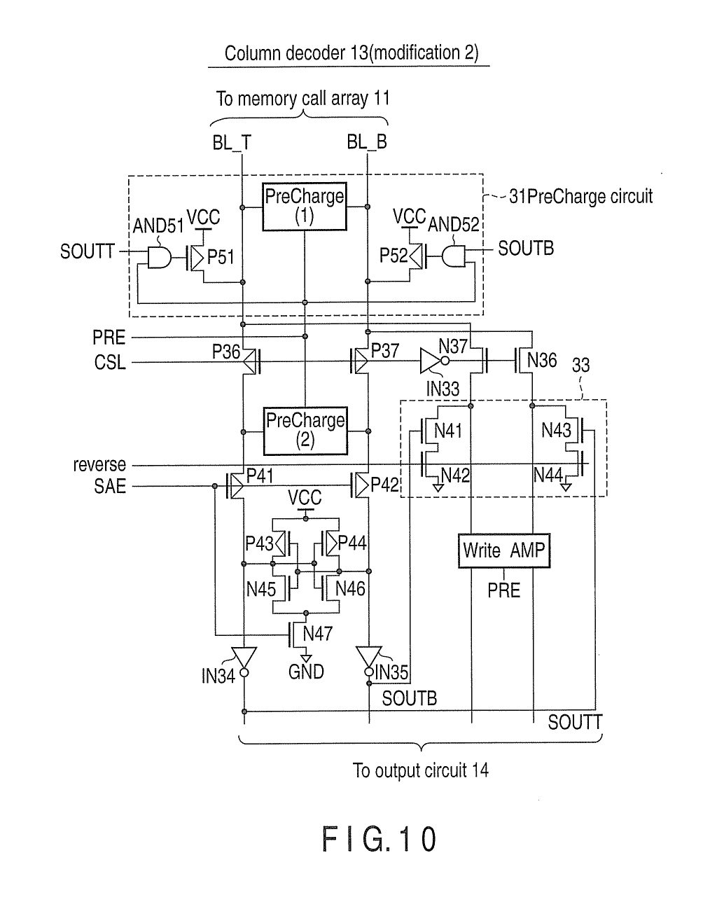

A semiconductor integrated circuit according to Modification 2 will be explained below with reference to FIG. 10. Modification 2 is directed to an example additionally including a precharge circuit 31 for assisting reverse data write. In this explanation, a repetitive explanation of the above-mentioned third embodiment will be omitted.

### Configuration Example

### Configuration Example of Memory Cell Unit

A configuration example of a memory cell unit will be explained below with reference to FIG. 10.

As shown in FIG. 10, this modification differs from the third embodiment in that a column decoder 13 includes the precharge circuit 31, a reversing circuit 33, transistors P36 to P52 and N36 to N47, inverters IN33 to IN35, precharge voltage generators (PreCharge) (1) and (2), and a write circuit Write AMP.

The precharge circuit 31 includes p-type transistors P51 and P52, AND circuits AND51 and AND52, and precharge voltage generator (1).

The p-type transistor P51 has a source connected to an internal power supply voltage VCC, a drain connected to precharge voltage generator (1), and a gate connected to the output of the AND circuit AND51. The p-type transistor P52 has a source connected to the internal power supply voltage VCC, a drain connected to precharge voltage generator (1), and a gate connected to the output of the AND circuit AND52.

The input of the AND circuit AND51 is connected to a signal SOUTT and the input of the AND circuit AND52. The input of the AND circuit AND52 is connected to a signal SOUTB.

Precharge voltage generator (1) is connected to bit lines BL_T and BL_B and precharge voltage generator (2).

### <Effects>

As described above, the semiconductor integrated circuit according to Modification 2 achieves at least the same effects as above-mentioned effects (1) and (2). In addition, the arrangement further including the precharge circuit 31 for assisting reverse data write as in this modification is applicable as needed.

### Modification 3

### Example of 8T Bit Cell (Dual-Port))

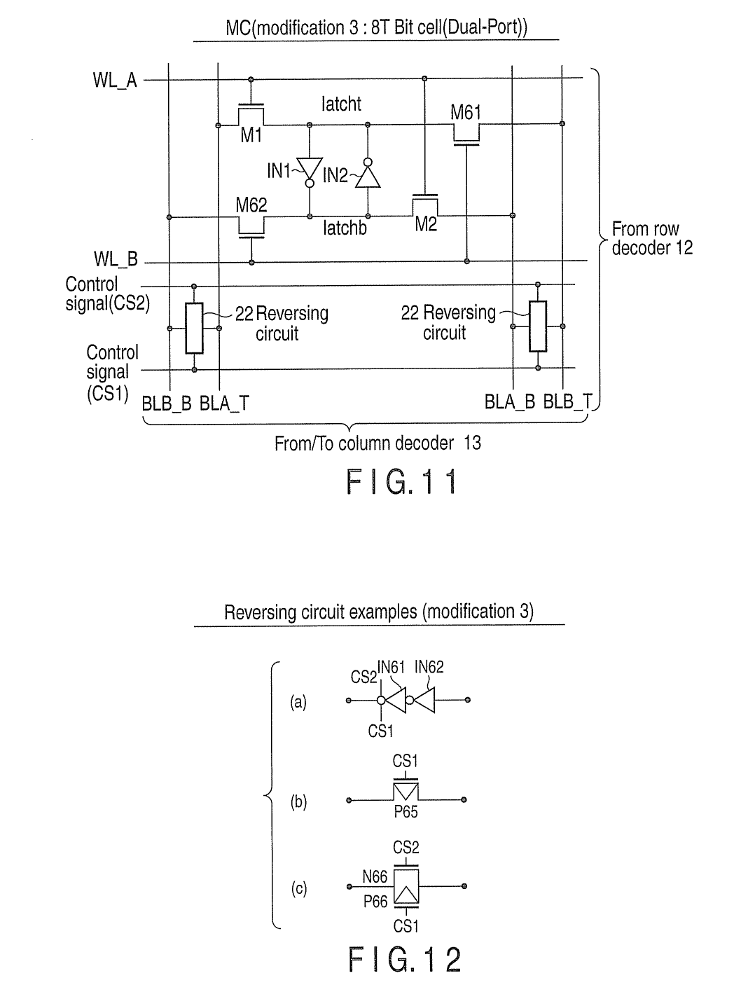

A semiconductor integrated circuit according to Modification 3 will be explained below with reference to FIGS. 11, 12A, 12B, 12C, and 13. This modification is directed to an 8T bit cell (dual-port). In this explanation, a repetitive explanation of the above-mentioned first embodiment will be omitted.

### Configuration Example

### Configuration Example of Memory Cell Unit

A configuration example of a memory cell unit will be explained below with reference to FIG. 11.

As shown in FIG. 11, a memory cell unit MC according to Modification 3 is an 8T bit cell (dual-port). This modification differs from the first embodiment in that the memory cell unit MC further includes bit lines BLB_B and BLB_T and reversing circuits 22.

The reversing circuits 22 are positioned between a bit line BLA_B and the bit line BLB_T and between the bit line BLB_B and a bit line BLA_T, and controlled by control signals CS1 and CS2.

### Configuration Examples of Reversing Circuit

FIGS. 12A, 12B, and 12C illustrate configuration examples of the reversing circuit 22 according to this modification.

In the example shown in FIG. 12A, the reversing circuit 22 includes inverters IN61 and IN62 connected in series between the bit lines BLA_B and BLB_T and between the bit lines BLB_B and BLA_T. The control signals CS1 and CS2 are input to the control terminal of the inverter IN61.

In the example shown in FIG. 12B, the reversing circuit 22 includes a p-type transistor P65 having a current path connected between the bit lines BLA_B and BLB_T and between the bit lines BLB_B and BLA_T. The control signal CS1 is input to the control terminal of the p-type transistor P65. In this example, the control signal CS2 is unnecessary.

In the example shown in FIG. 12C, a transmission gate of the reversing circuit 22 includes p- and n-type transistors P66 and N66 having current paths connected between the bit lines BLA_B and BLB_T and between the bit lines BLB_B and BLA_T. The control signals CS1 and CS2 are respectively input to the control terminals of the p- and n-type transistors P66 and N66.

### <Held Data Reversing Operation>

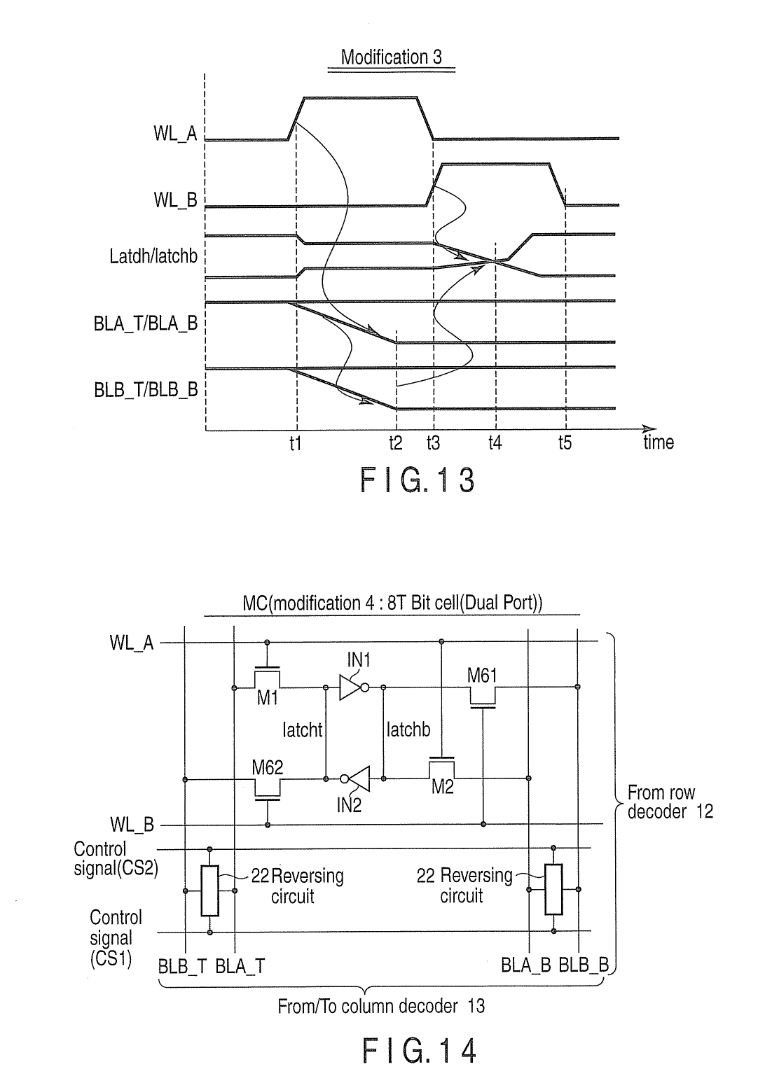

A held data reversing operation of the semiconductor integrated circuit according to Modification 3 will be explained below with reference to FIG. 13.

As shown in FIG. 13, this modification differs from the first embodiment in that at time t1, each of the bit lines BLA_B, BLA_T, BLB_B, and BLB_T operates as a selected line or unselected line.

### <Effects>

As described above, the semiconductor integrated circuit according to Modification 3 achieves at least the same effects as above-mentioned effects (1) and (2). In addition, this modification is applicable as needed.

### Modification 4

### Example of 8T Bit Cell (Dual-Port))

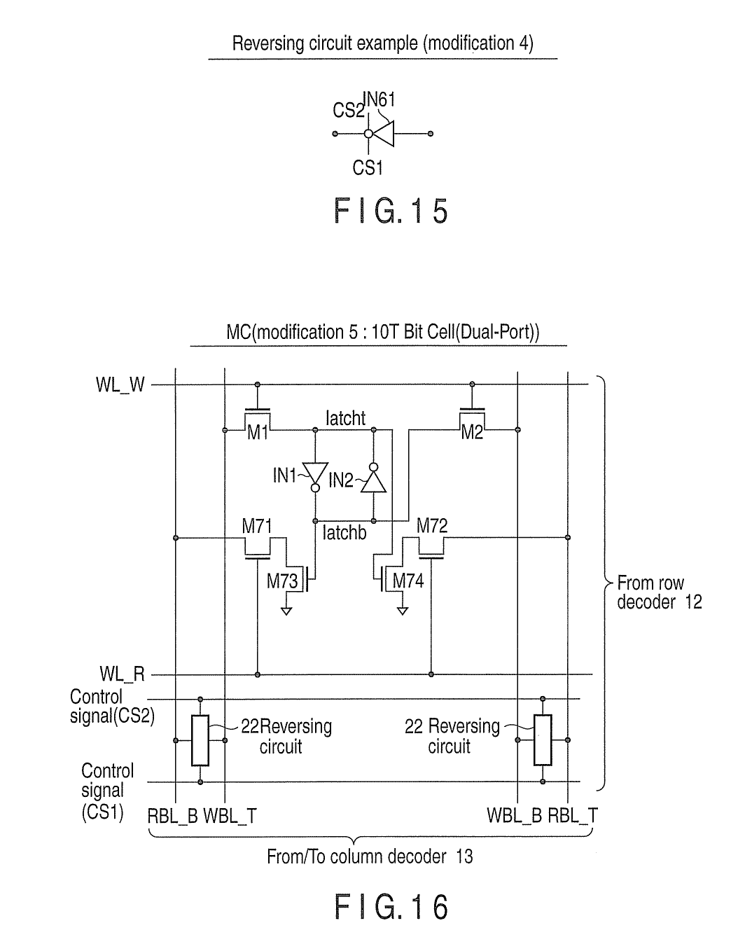

A semiconductor integrated circuit according to Modification 4 will be explained below with reference to FIGS. 14 and 15. This modification is directed to an 8T bit cell (dual-port). In this explanation, a repetitive explanation of above-mentioned Modification 3 will be omitted.

### Configuration Example

First, a configuration example of a memory cell unit will be explained below with reference to FIG. 14.

As shown in FIG. 14, a memory cell unit MC according to Modification 4 is an 8T bit cell (dual-port).

This modification differs from Modification 3 in that reversing circuits 22 are connected between bit lines BLA_B and BLB_T and between bit lines BLA_B and BLB_B.

The reversing circuits 22 are positioned between the bit lines BLA_B and BLB_B and between the bit lines BLA_T and BLB_T, and controlled by control signals CS1 and CS2.

### Configuration Example of Reversing Circuit

FIG. 15 shows a configuration example of the reversing circuit 22 according to this modification.

In this modification, the reversing circuit 22 includes an inverter IN61 connected in series between the bit lines BLA_T and BLB_T and between the bit lines BLA_B and BLB_B. The control signals CS1 and CS2 are input to the control terminal of the inverter IN61.

The rest of the arrangement and the operation are practically the same as those of Modification 3.

### <Effects>

As described above, the semiconductor integrated circuit according to Modification 4 achieves at least the same effects as above-mentioned effects (1) and (2). In addition, this modification is applicable as needed.

### Modification 5

### Example of 10T Bit Cell (Dual-Port))

A semiconductor integrated circuit according to Modification 5 will be explained below with reference to FIGS. 16, 17A, 17B, 17C, and 18. This modification is directed to a 10T bit cell (dual-port). In this explanation, a repetitive explanation of above-mentioned Modification 3 will be omitted.

### Configuration Example

### Configuration Example of Memory Cell Unit

A configuration example of a memory cell unit will be explained below with reference to FIG. 16.

As shown in FIG. 16, this modification differs from Modification 3 in that a memory cell unit MC further includes transistors M71 to M74 forming an SRAM cell, thereby forming a 10-transistor configuration.

The n-type transistor M71 has a source connected to the drain of the transistor M73, a drain connected to a bit line RBL_B, and a gate connected to a word line WL_R. The n-type transistor M72 has a source connected to the drain of the transistor M74, a drain connected to a bit line RBL_T, and a gate connected to the word line WL_R. The n-type transistor M73 has a source connected to a ground power supply voltage VSS, and a gate connected to a latch node latchb. The n-type transistor M74 has a source connected to the ground power supply voltage VSS, and a gate connected to a latch node latcht.

### Configuration Examples of Reversing Circuit

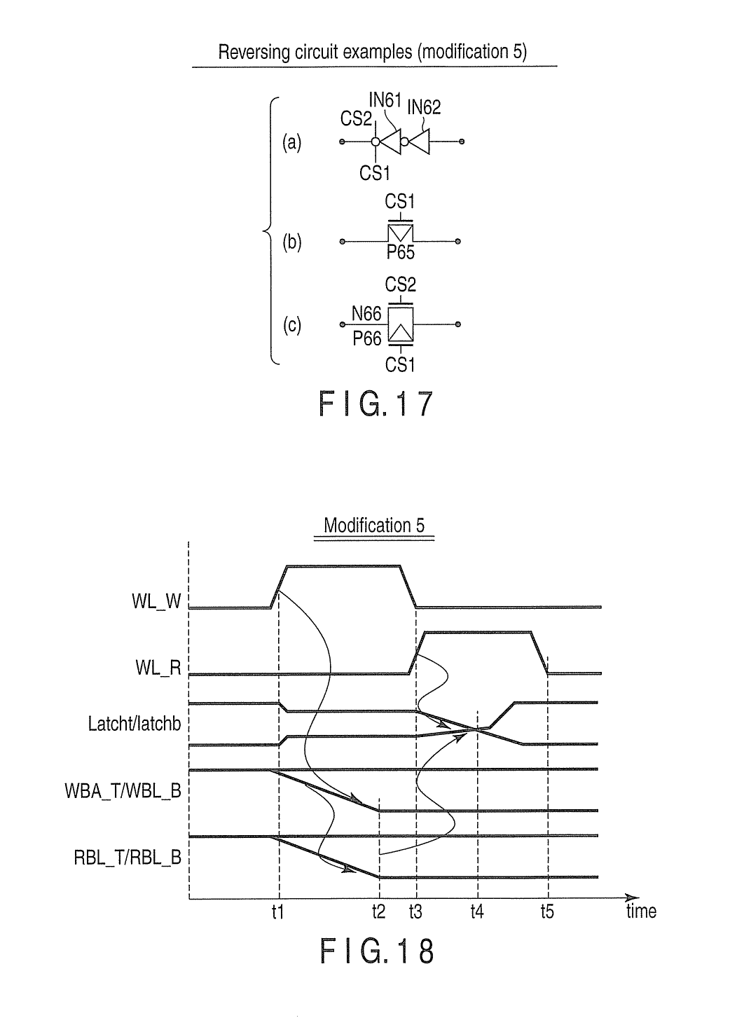

FIGS. 17A, 17B, and 17C illustrate configuration examples of a reversing circuit 22 according to this modification.

In the example shown in FIG. 17A, the reversing circuit 22 includes inverters IN61 and IN62 connected in series between the bit line RBL_B and a bit line WBL_T and between the bit line RBL_T and a bit line WBL_B. Control signals CS1 and CS2 are input to the control terminal of the inverter IN61.

In the example shown in FIG. 17B, the reversing circuit 22 includes a p-type transistor 965 having a current path connected between the bit lines RBL_B and WBL_T and between the bit lines RBL_T and WBL_B. The control signal CS1 is input to the control terminal of the p-type transistor 965. In this example, the control signal CS2 is unnecessary.

In the example shown in FIG. 17C, a transmission gate of the reversing circuit 22 includes p- and n-type transistors 966 and N66 having current paths connected between the bit lines RBL_B and WBL_T and between the bit lines RBL_T and WBL_B. The control signals CS1 and CS2 are respectively input to the control terminals of the p- and n-type transistors 966 and N66.

### <Held Data Reversing Operation>

FIG. 18 shows a held data reversing operation of the semiconductor integrated circuit according to Modification 5. As shown in FIG. 18, the held data reversing operation is practically the same as that of Modification 3.

### <Effects>

As described above, the semiconductor integrated circuit according to Modification 5 achieves at least the same effects as above-mentioned effects (1) and (2). In addition, this modification is applicable as needed.

### Modification 6

### Example of 10T Bit Cell (Dual-Port))

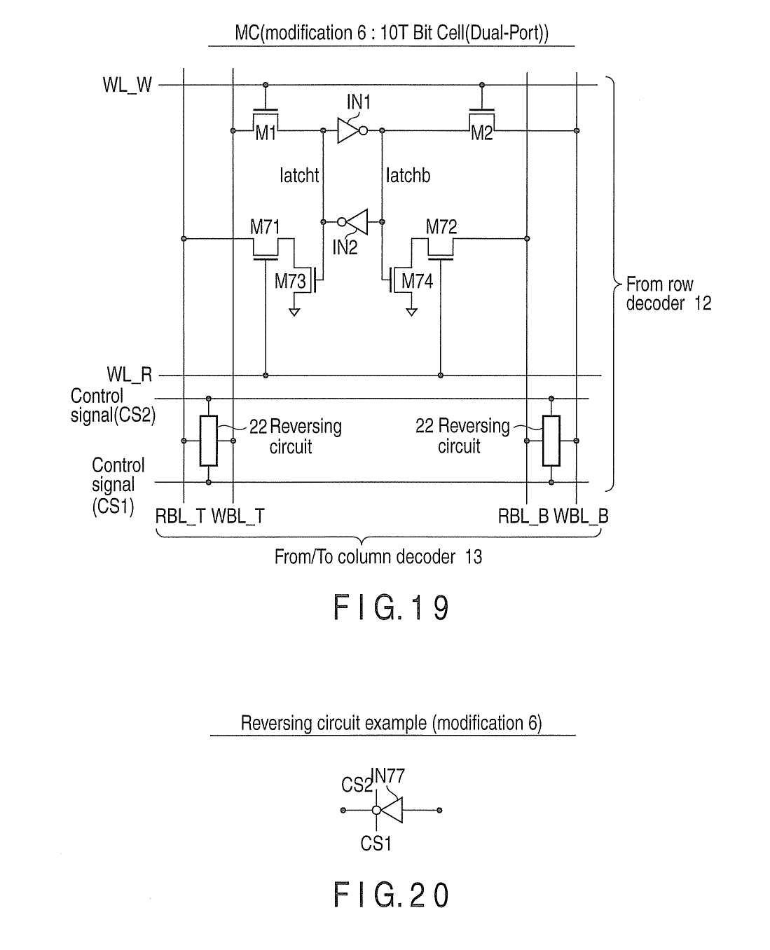

A semiconductor integrated circuit according to Modification 6 will be explained below with reference to FIGS. 19, 20, and 21. In this explanation, a repetitive explanation of the above-mentioned first embodiment will be omitted.

### Configuration Example

### Configuration Example of Memory Cell Unit

A configuration example of a memory cell unit will be explained below with reference to FIG. 19.

As shown in FIG. 19, a memory cell unit MC according to Modification 6 is a 10T bit cell (dual-port). This modification differs from Modification 5 in that reversing circuits 22 are connected between bit lines RBL_T and WBL_T and between bit lines RBL_B and WBL_B.

The reversing circuits 22 are positioned between the bit lines RBL_T and WBL_T and between the bit lines RBL_B and WBL_B, and controlled by control signals CS1 and CS2.

### Configuration Example of Reversing Circuit

A configuration example of the reversing circuit 22 will be explained below with reference to FIG. 20.

As shown in FIG. 20, the reversing circuit 22 includes an inverter IN77 connected in series between the bit lines RBL_T and WBL_T and between the bit lines RBL_B and WBL_B. The control signals CS1 and CS2 are input to the control terminal of the inverter IN77.

### <Held Data Reversing Operation>

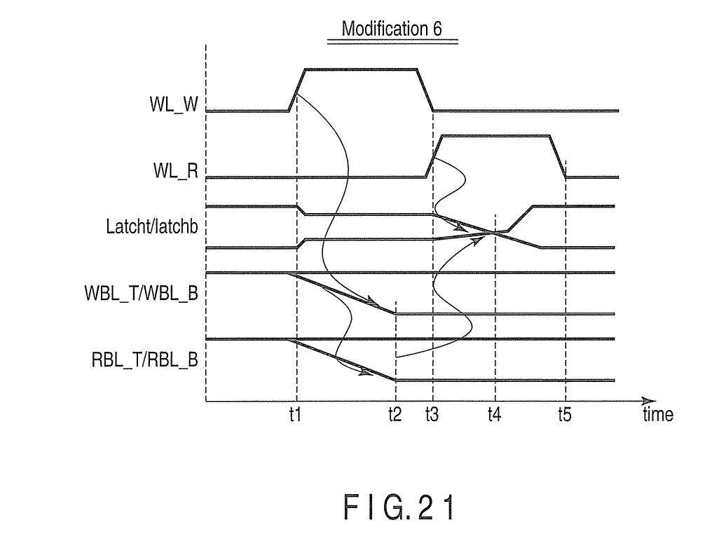

FIG. 21 shows a held data reversing operation of the semiconductor integrated circuit according to Modification 6. As shown in FIG. 21, the held data reversing operation is practically the same as that of Modification 5.

### <Effects>

As described above, the semiconductor integrated circuit according to Modification 6 achieves at least the same effects as above-mentioned effects (1) and (2). In addition, this modification is applicable as needed.

Note that as disclosed in the embodiments and modifications, the present embodiment is similarly applicable to an example in which the memory cell unit MC has a write line and read line (a write port and read port), a 2-port SRAM cell, or a 1-port SRAM cell (8Tr or 10Tr bit cell) using a bit cell having a read only port, and the same effects can be obtained. Likewise, the WL line, WL_R line, and the like can also be used as word lines of other ports, such as write word lines, in the normal mode.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor integrated circuit comprising a memory cell array comprising data storage units which are arranged at intersections of word lines and bit lines and hold data, a reversing circuit which logically reverses held data stored in the data storage units, and a flag bit column which stores, for each row, a flag for identifying presence/absence of logic reversal of data stored in the data storage units.

2. The circuit of claim 1, further comprising an output circuit which selectively outputs readout data from the data storage units in accordance with data read out from the flag bit column.

3. The circuit of claim 1, further comprising a flag bit circuit which performs flag bit data write or data read with respect to the flag bit column, and switches data of the data storage units for each row by software.

4. The circuit of claim 1, wherein the reversing circuit comprises a first transistor and a second transistor, a current path of each of the first transistor and the second transistor having one end connected to the bit line and the other end connected to a latch node of the data storage unit, and gates of the first transistor and the second transistor being connected to the word line.

5. The circuit of claim 4, wherein the data storage unit comprises:
a third transistor and a fourth transistor, a current path of each of the third transistor and the fourth transistor having one end connected to the bit line and the other end connected to the latch node, and gates of the third transistor and the fourth transistor being connected to the word line; and
a first inverter and a second inverter, an input of the first inverter being connected to an output of the second inverter, and an output of the first inverter being connected to an input of the second inverter.

6. The circuit of claim 1, further comprising a control signal circuit which supplies a control signal to the reversing circuit.

7. The circuit of claim 6, wherein the reversing circuit comprises:
a reverse data write circuit which receives the control signal from the control signal circuit, and writes reverse data in the reversing circuit;
a data latch circuit which latches the reverse data; and
a data latch input circuit which receives the reverse data.

8. A semiconductor integrated circuit comprising:
a memory cell array comprising memory cell units including data storage units which are arranged at intersections of word lines and bit lines and hold data, and a flag bit column which stores, for each row, a flag for identifying presence/absence of logic reversal of data stored in the memory cell units; and
a column decoder comprising a reversing circuit which logically reverses held data stored in the data storage units, and a precharge signal generator which, in a data reverse mode, applies a precharge voltage to a bit line to be selected, and generates a control signal for assisting reverse data write.

9. The circuit of claim 8, further comprising an output circuit which selectively outputs readout data from the data storage units in accordance with data read out from the flag bit column.

10. The circuit of claim 8, further comprising a flag bit circuit which performs flag bit data write or data read with respect to the flag bit column, and switches data of the memory cell units for each row by software.

11. The circuit of claim 8, wherein the reversing circuit comprises a first transistor and a second transistor, a current path of each of the first transistor and the second transistor having one end connected to the bit line and the other end connected to a latch node of the data storage unit, and gates of the first transistor and the second transistor being connected to the word line.

12. The circuit of claim 11, wherein the data storage unit comprises:
a third transistor and a fourth transistor, a current path of each of the third transistor and the fourth transistor having one end connected to the bit line and the other end connected to the latch node, and gates of the third transistor and the fourth transistor being connected to the word line; and
a first inverter and a second inverter, an input of the first inverter being connected to an output of the second inverter, and an output of the first inverter being connected to an input of the second inverter.

13. The circuit of claim 8, further comprising a reversal controller which controls the reversing circuit.

14. The circuit of claim 8, wherein the precharge signal generator receives a precharge signal, and outputs the control signal in accordance with readout data from the memory cell unit.

15. A semiconductor integrated circuit comprising:
data storage units which are arranged at intersections of word lines and bit lines and hold data; and
a reversing circuit which logically reverses held data stored in the data storage units,
wherein the data storage units are arranged at intersections of a pair of a first word line and a second word line, and a pair of a first bit line and a second bit line, and the reversing circuit is positioned between the pair of the first bit line and the second bit line, and controlled by a control signal.

16. The circuit of claim 15, further comprising a flag bit column which stores, for each row, a flag for identifying presence/absence of logic reversal of data stored in the data storage units.

17. The circuit of claim 16, further comprising an output circuit which selectively outputs readout data from the data storage units in accordance with data read out from the flag bit column.

18. The circuit of claim 16, further comprising a flag bit circuit which performs flag bit data write or data read with respect to the flag bit column, and switches data of the data storage units for each row by software.

19. The circuit of claim 15, wherein the data storage unit comprises:
a third transistor and a fourth transistor, a current path of each of the third transistor and the fourth transistor having one end connected to the bit line and the other end connected to a latch node, and gates of the third transistor and the fourth transistor being connected to the word line; and
a first inverter and a second inverter, an input of the first inverter being connected to an output of the second inverter, and an output of the first inverter being connected to an input of the second inverter.

20. The circuit of claim 15, further comprising a control signal circuit which supplies a control signal to the reversing circuit.
